(19) United States
(12) Patent Application Publication
(10) Pub. No.: US 2014/0360575 A1
(43) Pub. Date: Dec. 11, 2014

(54) COLORED SOLAR CELL DEVICE

(71) Applicant: NEXPOWER TECHNOLOGY CORPORATION, Taichung City (TW)

(72) Inventors: Gwo-Sen Lin, Taichung City (TW); Fu-Ji Tsai, New Taipei City (TW)

(73) Assignee: NEXPOWER TECHNOLOGY CORPORATION, Taichung City (TW)

(21) Appl. No.: 13/912,008

(22) Filed: Jun. 6, 2013

(51) Int. Cl. H01L 31/052

(52) U.S. Cl. CPC H01L 31/0528
USPC 136/257

(57) ABSTRACT

A colored solar cell device includes: a solar cell module; a transparent adhesive layer; and a color filter attached to the solar cell module through the transparent adhesive layer and including a transparent filter substrate and a wavelength-selective reflecting film that is formed on the transparent filter substrate, that contacts the transparent adhesive layer and that includes at least one first dielectric layer made from a material selected from the group consisting of TiO₂, Nb₂O₃, ZnS, and ZrO₂. The first dielectric layer has a thickness ranging from 1 nm to 300 nm. The transparent filter substrate has a refractive index n₀. The first dielectric layer has a refractive index n₁ greater than n₀.

### BACKGROUND OF THE INVENTION

1. Field of the Invention

This invention relates to a colored solar cell device, more particularly to a colored solar cell device including a solar cell module and a color filter attached to the solar cell module.

2. Description of the Related Art

FIG. 1 illustrates a conventional colored solar cell device 1 disclosed in U.S. Patent Application Publication No. 2010/0096011 (USPA '011). The conventional colored solar cell device 1 includes a color filter 11, a solar cell module 12, and an optical coupling material 13 glued between the color filter 11 and the solar cell module 12.

The color filter 11 includes a transparent substrate 111, a first reflective layer 112, a spacer layer 113 and a second reflective layer 114 which are stacked one above another.

Each of the first and second reflective layers 112, 114 has a thickness ranging from 2 nm to 30 nm, and is made from a material, such as amorphous silicon, polysilicon, aluminum, silver, gold, molybdenum, titanium, tungsten, chromium, and chromium molybdenum alloy. The spacer layer 113 can be air or can be made from a transparent material with a refractive index (n) ranging from 1 to 3.

In one example (see FIG. 5C in the specification of USPA '011), the color filter 11 of the conventional colored solar cell device 1 has a maximum transmittance of less than 20% for a visible wavelength band ranging from about 390 nm to 720 nm. In this example, the first reflective layer 112 is made from Mo and has a thickness of 50 Å, the second reflective layer 114 is made from Al and has a thickness of 60 Å, and the spacer layer 113 is made from silicon dioxide and has a thickness of 1800 Å. In another example (see FIG. 5G in the specification of USPA '011), the color filter 11 of the conventional colored solar cell device 1 has a transmittance ranging from 10% to 70% for a visible wavelength band ranging from about 390 nm to 720 nm. In this example, the first and second reflective layers 112, 114 are made from amorphous silicon and each have a thickness of 70 Å, and the spacer layer 113 is made from silicon dioxide and has a thickness of 1500 Å.

Although the color filter 11 can impart a desired color to the conventional colored solar cell device 1, its transmittance of visible light is relatively low, which results in a reduction in the photoelectric conversion efficiency of the conventional colored solar cell device 1.

### SUMMARY OF THE INVENTION

Therefore, an object of the present invention is to provide a colored solar cell device that can improve the photovoltaic conversion efficiency thereof.

According to one aspect of this invention, there is provided a colored solar cell device. The colored solar cell device comprises: a solar cell module having a light-incident side; a transparent adhesive layer; and a color filter attached to the light-incident side of the solar cell module through the transparent adhesive layer and including a transparent filter substrate and a wavelength-selective reflecting film that is formed on the transparent filter substrate, that contacts the transparent adhesive layer, and that includes at least one first dielectric layer which is made from a material selected from the group consisting of TiO₂, Nb₂O₃, ZnS, and ZrO₂. The first dielectric layer has a thickness ranging from 1 nm to 300 nm. The transparent filter substrate has a refractive index n₀. The first dielectric layer has a refractive index n₁ that is greater than n₀.

According to another aspect of the present invention, there is provided a colored solar cell device. The colored solar cell device comprises: a lower substrate; an adhesive layer; a solar cell having a light-incident side and attached to the lower substrate through the adhesive layer; and a color filter formed on the light-incident side of the solar cell and including a transparent filter substrate and a dielectric layer which is made from a material selected from the group consisting of TiO₂, Nb₂O₃, ZnS, and ZrO₂, and which has a thickness ranging from 1 nm to 300 nm. The transparent filter substrate has a refractive index n₀. The dielectric layer has a refractive index n₁ which is greater than n₀.

### BRIEF DESCRIPTION OF THE DRAWINGS

In drawings which illustrate embodiments of the invention, FIG. 1 is a schematic view of a conventional colored solar cell device disclosed in U.S. Patent Application Publication NO. 2010/0096011 A1;

FIG. 2 is a schematic view of the first preferred embodiment of a colored solar cell device according to the present invention;

FIG. 3 is a schematic view of the second preferred embodiment of the colored solar cell device according to the present invention;

FIG. 4 is a top view of the third preferred embodiment of the colored solar cell device according to the present invention;

FIG. 5 is a sectional view taken along the line V-V in FIG. 4;

FIG. 6 is a fragmentary sectional view of the fourth preferred embodiment of the colored solar cell device according to the present invention;

FIG. 7 is a sectional view of the fifth preferred embodiment of the colored solar cell device according to the present invention;

FIG. 8 is a diagram showing the transmittance of a color filter of Example 1;

FIG. 9 is a diagram showing the transmittance of a color filter of Example 2;

FIG. 10 is a diagram showing the transmittance of a color filter of Example 3;

FIG. 11 is a diagram showing the transmittance of a color filter of Example 4;

FIG. 12 is a diagram showing the reflectance of a color filter of Example 5;

FIG. 13 is a diagram showing the reflectance of a color filter of Example 6;

FIG. 14 is a diagram showing the reflectance of a color filter of Example 7; and

FIG. 15 is a diagram showing the reflectance of a color filter of Example 8.

### DETAILED DESCRIPTION OF THE PREFERRED EMBODIMENTS

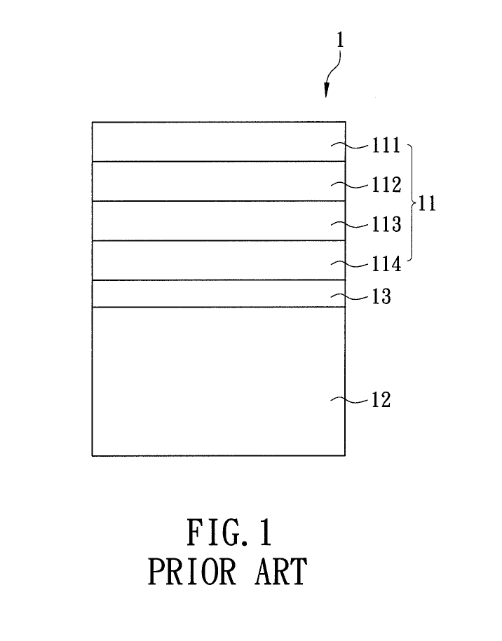

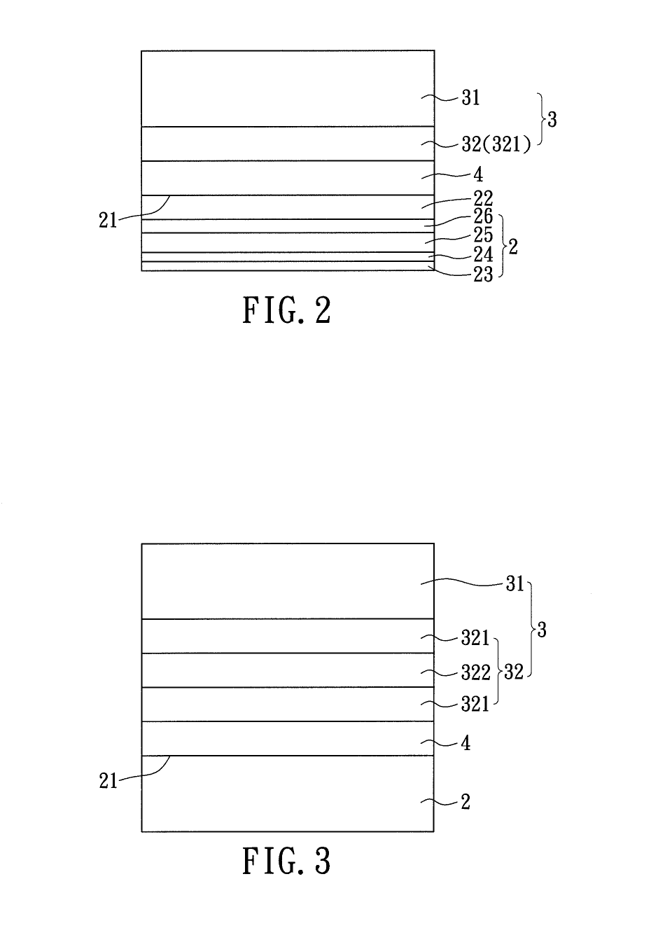

FIG. 2 illustrates the first preferred embodiment of a colored solar cell device according to the present invention. The first preferred embodiment comprises a solar cell module 2 with a light-incident side 21, a transparent adhesive layer 4, and a color filter 3.

The solar cell module 2 employed in the solar cell device of the preferred embodiment can be obtained from commercially available sources. In this embodiment, the solar cell module 2 includes a substrate 23, a first conductor layer 24 that is formed on the substrate 23, a semiconductor layered structure 25 that is formed on the first conductor layer 24 and that receives and converts light into electric energy, a second conductor layer 26 that is formed on the semiconductor layered structure 25, and a top cover layer 22 that is formed on the second conductor layer 26 and that has the light-incident side 21. The top cover layer 22 is made from a transparent material, such as glass.

The transparent adhesive layer 4 has a refractive index n_{B}, and is preferably made from an encapsulating material.

The color filter 3 is attached to the light-incident side 21 of the solar cell module 2 through the transparent adhesive layer 4. The color filter 3 includes a transparent filter substrate 31 and a wavelength-selective reflective film 32. The wavelength-selective reflective film 32 is formed on the transparent filter substrate 31, contacts the transparent adhesive layer 4, and includes a first dielectric layer 321. The first dielectric layer 321 is made from a material selected from the group consisting of TiO₂, Nb₂O₃, ZnS, and ZrO₂. The first dielectric layer 321 has a thickness ranging from 1 nm to 300 nm. The transparent filter substrate 31 has a refractive index n₀. The first dielectric layer 321 has a refractive index n₁ which is greater than n₀ and n_{B}.

The color filter 3 can reflect an incident light (such as the sunlight) in a reflected visible wavelength band and transmits the incident light in a transmitted visible wavelength band(s) therethrough. The incident light in the transmitted visible wavelength band(s) enters the solar cell module 2 through the light-incident side 21 of the solar cell module 2, and is converted into electrical energy. The color filter 3 has a transmittance greater than 80% in the transmitted visible wavelength band(s).

When the light-incident side 21 of the solar cell module 2 is made from a material similar to or the same as that of the transparent filter substrate 31, such as glass, the refractive index n_{B} of the transparent adhesive layer 4 is required to be close to the refractive index of the light-incident side 21 of the solar cell module 2. Alternatively, in a modified embodiment, when the top cover layer 22 is dispensed with and when the light-incident side 21 of the solar cell module 2 is made from a semiconductor material, for instance, a copper indium selenium (CIS)-based semiconductor material, the refractive index n_{B} is required to be smaller than the refractive index of the light-incident side 21 of the solar cell module 2.

In one example of the first preferred embodiment, in which the incident light has a visible wavelength band ranging from 400 nm to 720 nm and in which the thickness of the first dielectric layer 321 of the color filter 3 ranges from 70 nm to 90 nm, the color filter 3 reflects the incident light in a reflected visible wavelength band that ranges from 540 nm to 650 nm (similar to golden color), and transmits the incident light in a transmitted visible wavelength band ranging from 400 nm to 540 nm and another transmitted visible wavelength band ranging from 650 nm to 720 nm with an average transmission of each transmitted visible wavelength band of greater than 90%.

FIG. 3 illustrates the second preferred embodiment of the colored solar cell device according to the present invention. The second preferred embodiment differs from the previous embodiment in that the wavelength-selective reflective film 32 further includes a second dielectric layer 322, and that the number of the first dielectric layer 321 is two. The second dielectric layer 322 is disposed between the first dielectric layers 321, and is preferably made from a material selected from the group consisting of SiO₂, LiF, and MgF₂. The second dielectric layer 322 has a thickness that ranges from 1 nm to 100 nm.

In a first example of the second preferred embodiment, in which the incident light has a visible wavelength band ranging from 400 nm to 720 nm and in which the thickness of the first dielectric layer 321 which is disposed adjacent to the transparent filter substrate 31 ranges from 80 nm to 100 nm, the thickness of the second dielectric layer 322 ranges from 5 nm to 20 nm, and the thickness of the first dielectric layer 321 which is disposed distal from the transparent filter substrate 31 ranges from 95 nm to 115 nm, the color filter 3 reflects the incident light in a reflected visible wavelength band that ranges from 600 nm to 720 nm (similar to red color), and transmits the incident light in a transmitted visible wavelength band ranging from 400 nm to 600 nm with an average transmittance of greater than 90% in the transmitted visible wavelength band.

In a second example of the second preferred embodiment, in which the thickness of the first dielectric layer 321 which is disposed adjacent to the transparent filter substrate 31 ranges from 55 nm to 70 nm, the thickness of the second dielectric layer 322 ranges from 4 nm to 8 nm, and the thickness of the first dielectric layer 321 which is disposed distal from the transparent filter substrate 31 ranges from 70 nm to 88 nm, the color filter 3 reflects the incident light in a reflected visible wavelength band that ranges from 450 nm to 600 nm (similar to green color), and transmits the incident light in a transmitted visible wavelength band ranging from 400 nm to 450 nm and another transmitted visible wavelength band from 600 nm to 720 nm with an average transmittance of greater than 88% in each transmitted wavelength band.

In a third example of the second preferred embodiment, in which the thickness of the first dielectric layer 321 which is disposed adjacent to the transparent filter substrate 31 ranges from 110 nm to 135 nm, the thickness of the second dielectric layer 322 ranges from 40 nm to 50 nm, and the thickness of the first dielectric layer 321 which is distal from the transparent filter substrate 31 ranges from 6 nm to 15 nm, the color filter 3 reflects the incident light in a reflected visible wavelength band that ranges from 420 nm to 550 nm (similar to blue color), and transmits the incident light in a transmitted visible wavelength band ranging from 550 nm to 720 nm with an average transmittance of greater than 90% in the transmitted visible wavelength band.

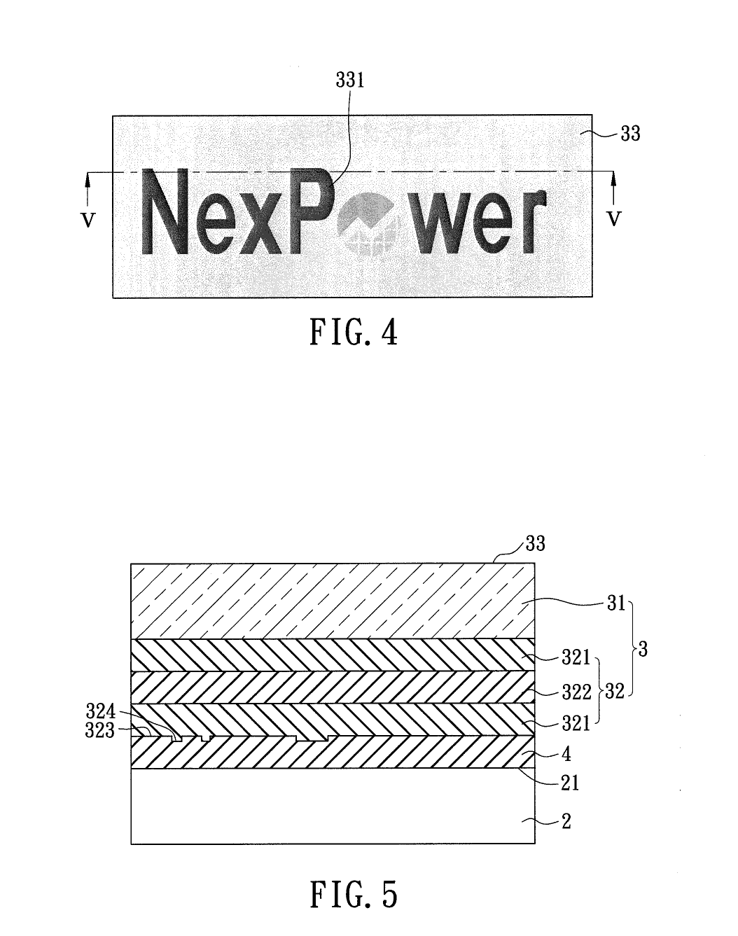

FIGS. 4 and 5 illustrate the third preferred embodiment of the colored solar cell device according to the present invention. The third preferred embodiment differs from the second preferred embodiment in that the first dielectric layer 321 which is distal from the transparent filter substrate 31 has a bottom surface 323 that contacts the transparent adhesive layer 4, and a predetermined pattern 324 that protrudes from the bottom surface 323 into the transparent adhesive layer 4. The color filter 3 is capable of reflecting the incident light in the desired reflected visible wavelength band to form an image 331 corresponding to the predetermined pattern 324.

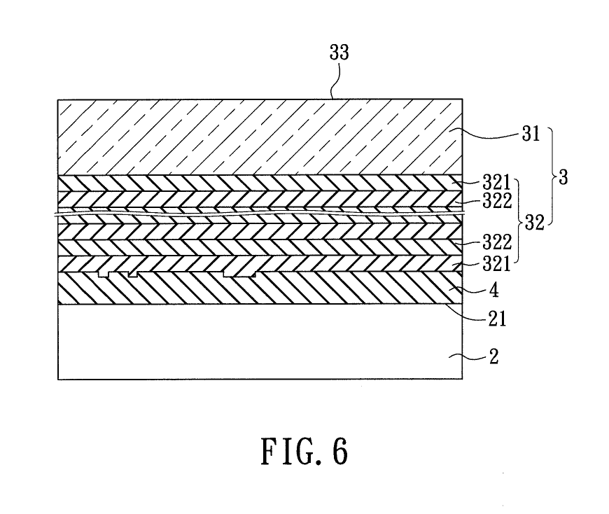

FIG. 6 illustrates the fourth preferred embodiment of the colored solar cell device according to the present invention. The fourth preferred embodiment differs from the third preferred embodiment in that the color filter 3 includes a transparent filter substrate 31, and a wavelength-selective reflective film 32 that includes a plurality of first dielectric layers 321, and a plurality of second dielectric layers 322. The number of the first dielectric layer 31 is greater than that of the second dielectric layers 32. Each of the first dielectric layer 321 is preferably made from a material selected from the group consisting of TiO₂, Nb₂O₃, ZnS, and ZrO₂. Each of the second dielectric layers 322 is preferably made from a material selected from the group consisting of SiO₂, LiF, and MgF₂. The first and second dielectric layers 321, 322 are alternately disposed. The transparent filter substrate 31 and the transparent adhesive layer 4 are respectively in contact with two endmost ones of the first dielectric layers 321. Each of the second dielectric layers 322 has a refractive index n₂ that is less than the refractive index n₁ of the first dielectric layer 321. The thickness of each of the first and second dielectric layers 321, 322 ranges from 1 nm to 150 nm.

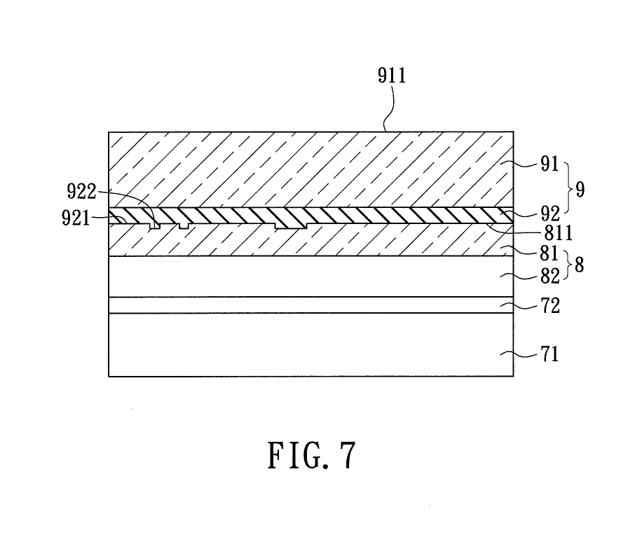

FIG. 7 illustrates the fifth preferred embodiment of the colored solar cell device according to the present invention. The fifth preferred embodiment comprises a lower substrate 71, an adhesive layer 72, a solar cell 8, and a color filter 9.

The solar cell 8 is attached to the lower substrate 71 through the adhesive layer 72, and includes a transparent conductive layer 81 with a light-incident side 811, and a semiconductor layered structure 82 that contacts the adhesive layer 72 and that contains photovoltaic active materials. The transparent conductive layer 81 has a thickness that ranges from 500 nm to 3000 nm. The transparent conductive layer 81 is preferably made from a transparent conductive material that has a refractive index ranging from 1.5 to 2.1, and that is selected from the group consisting of In—SnO, F—SnO, Al—ZnO, B—ZnO, and Ga—ZnO.

The color filter 9 is directly formed on the light-incident side 811 of the solar cell 8. The color filter 9 includes a transparent filter substrate 91 and a dielectric layer 92. The transparent filter substrate 91 has a refractive index n₀. The dielectric layer 92 has a refractive index n₁ that is greater than n₀. The dielectric layer 92 is preferably made from a material selected from the group consisting of TiO₂, Nb₂O₃, ZnS, and ZrO₂. The thickness of the dielectric layer 92 ranges from 1 nm to 300 nm.

The color filter 9 thus formed can achieve the goal of reflecting light in a desired reflected visible wavelength band and transmitting light in a transmitted visible wavelength band with a transmittance of greater than 80% in the transmitted visible wavelength band.

In this embodiment, the dielectric layer 92 has a bottom surface 921 that contacts the solar cell 8, and a predetermined pattern 922 that protrudes from the bottom surface 921 into the solar cell 8. The color filter 9 is capable of reflecting the incident light in the desired reflected visible wavelength band to form an image (not shown) corresponding to the predetermined pattern 922.

Ina first example of the fifth preferred embodiment, in which the thickness of the dielectric layer 92 of the color filter 9 ranges from 70 nm to 90 nm, the color filter 9 reflects the incident light in a reflected visible wavelength band that ranges from 540 nm to 650 nm (similar to golden color), and transmits the incident light in a transmitted visible wavelength band ranging from 400 nm to 540 nm and another transmitted visible wavelength band ranging from 650 nm to 720 nm with an average transmittance of greater than 85% in each transmitted visible wavelength band.

In a second example of the fifth preferred embodiment, in which the thickness of the dielectric layer 92 of the color filter 9 ranges from 180 nm to 210 nm, the color filter 9 reflects the incident light in a reflected visible wavelength band that ranges from 600 nm to 720 nm (similar to red color), and transmits the incident light in a transmitted visible wavelength band ranging from 400 nm to 600 nm with an average transmittance of greater than 85% in the transmitted visible wavelength band.

In a third example of the fifth preferred embodiment, in which the thickness of the dielectric layer 92 of the color filter 9 ranges from 210 nm to 250 nm, the color filter 9 reflects the incident light in a reflected visible wavelength band that ranges from 450 nm to 600 nm (similar to green color), and transmits the incident light in a transmitted visible wavelength band ranging from 400 nm to 450 nm and another transmitted visible wavelength band ranging from 600 nm to 720 nm with an average transmittance of greater than 88% in each transmitted visible wavelength band.

In a fourth example of the fifth preferred embodiment, in which the thickness of the dielectric layer 92 of the color filter 9 ranges from 100 nm to 120 nm, the color filter 9 reflects the incident light in a reflected visible wavelength band that ranges from 400 nm to 550 nm (similar to blue color), and transmits the incident light in a transmitted visible wavelength band ranging from 550 nm to 720 nm with an average transmittance of greater than 90% in the transmitted visible wavelength band.

The following examples are provided to illustrate the merit of the preferred embodiments of the invention, and should not be construed as limiting to the scope of the invention.

### EXAMPLES

### Example 1 (E1)

The solar cell module of Example 1 (E1) having a structure the same as that of FIG. 2 was prepared. In addition, the semiconductor layered structure of the solar cell was prepared from an amorphous silicon.

A TiO₂ layer (serving as a reflective film) with a thickness of about 88.02 nm and a reflective index between 2.3 and 2.5 was formed on a transparent filter substrate by sputtering techniques so as to form a color filter of Example 1 (E1).

The light-incident side of the solar cell module was attached to the reflective film of the color filter through a polyvinyl butyral (PVB) adhesive with a refractive index of between 1.4 and 1.5 so as to form a solar cell device of Example 1 (E1).

### Example 2 (E2)

A TiO₂ layer with a thickness of about 94.90 nm, a SiO₂ layer with a thickness of about 15.29 nm and a refractive index of between 1.4 and 1.5, and a TiO₂ layer with a thickness of about 113.38 nm were formed on a transparent filter substrate by sputtering techniques so as to form a color filter of Example 2 (E2). The color filter was attached to a solar cell module having a structure the same as that of Example 1 (E1) through a PVB adhesive so as to form the solar cell device of Example 2 (E2).

### Example 3 (E3)

A TiO₂ layer with a thickness of about 68.23 nm, a SiO₂ layer with a thickness of about 6.35 nm, and a TiO₂ layer with a thickness of about 85.49 nm were formed on a transparent filter substrate by sputtering techniques so as to form a color filter of Example 3 (E3). The color filter was attached to a solar cell module having a structure the same as that of Example 1 (E1) through a PVB adhesive so as to form the solar cell device of Example 3 (E3).

### Example 4 (E4)

A TiO₂ layer with a thickness of about 130.80 nm, a SiO₂ layer with a thickness of about 49.75 nm, and a TiO₂ layer with a thickness of about 13.05 nm were formed on a transparent filter substrate by sputtering techniques so as to forma color filter of Example 4 (E4). The color filter was attached to a solar cell module having a structure the same as that of Example 1 (E1) through a PVB adhesive so as to form the solar cell device of Example 4 (E4).

### Example 5 (E5)

A TiO₂ layer (serving as a reflective film) with a thickness of about 83 nm was formed on a transparent filter substrate by sputtering techniques so as to form a color filter of Example 5 (E5).

A ZnO layer doped with B(ZnO:B) (serving as a transparent conductive layer) and having a thickness of about 1200 nm and a refractive index of about 2.0 was formed on the TiO₂ layer. An amorphous silicon layer and a microcrystalline layer, cooperatively serving as a photovoltaic semiconductor structure, were formed on the ZnO layer. A lower electrode layer was formed on the microcrystalline layer. A lower substrate was attached to the lower electrode layer through a PVB adhesive so as to form the solar cell device of Example 5 (E5).

### Example 6 (E6)

Preparation of the solar cell device of Example 6 (E6) was different from that of Example 5 (E5) only in the thickness of the TiO₂ layer. In Example 6 (E6), the TiO₂ layer with a thickness of about 197 nm was formed on the transparent filter substrate so as to form a color filter of Example 6 (E6).

### Example 7 (E7)

Preparation of the solar cell device of Example 7 (E7) was different from that of Example 5 (E5) only in the thickness of the TiO₂ layer. In Example 7 (E7), the TiO₂ layer with a thickness of about 237 nm was formed on the transparent filter substrate so as to form the color filter of Example 7 (E7).

### Example 8 (E8)

Preparation of the solar cell device of Example 8 (E8) was different from that of Example 5 (E5) only in the thickness of the TiO₂ layer. In Example 8 (E8), the TiO₂ layer with a thickness of about 115 nm was formed on the transparent filter substrate so as to form the color filter of Example 8 (E8).

### <Analysis Data>

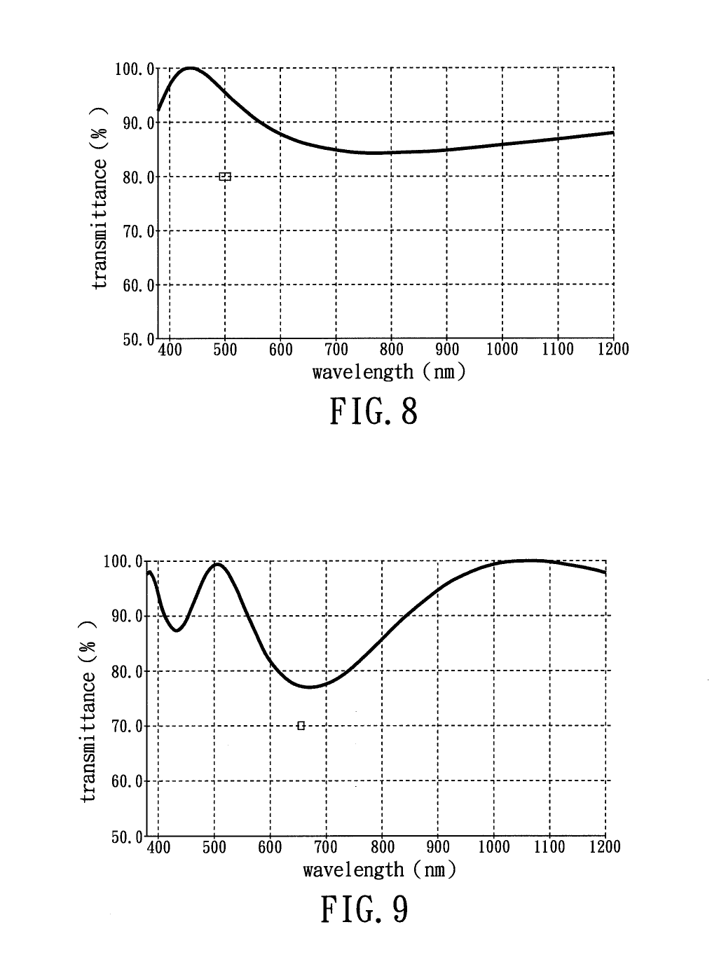

FIG. 8 is a diagram showing the transmittance of the color filter of Example 1 (E1). The color filter has a transmittance of between 90% and 100% in a wavelength band from 400 nm to 560 nm and between 85% and 90% in another wavelength band from 560 nm to 720 nm, and has an average transmittance of greater than 90% in a wavelength band from 400 nm to 720 nm and greater than 85% in a wavelength band from 400 nm to 1200 nm. Measured by a colorimeter, the color filter has a chromaticity coordinate of (x=0.49, y=0.46) in a CIE 1931 chromaticity coordinate diagram (not shown), which indicates a color close to golden color.

FIG. 9 is a diagram showing the transmittance of the color filter of Example 2 (E2). The color filter has a transmittance of between 80% and 100% in a wavelength band from 400 nm to 610 nm and between 77% and 80% in another wavelength band from 610 nm to 720 nm, and has an average transmittance of greater than 90% in a wavelength band from 400 nm to 720 nm and greater than 85% in a wavelength band from 400 nm to 1200 nm. Measured by a colorimeter, the color filter has a chromaticity coordinate of (x=0.44, y=0.3) in a CIE 1931 chromaticity coordinate diagram (not shown), which indicates a color close to red color.

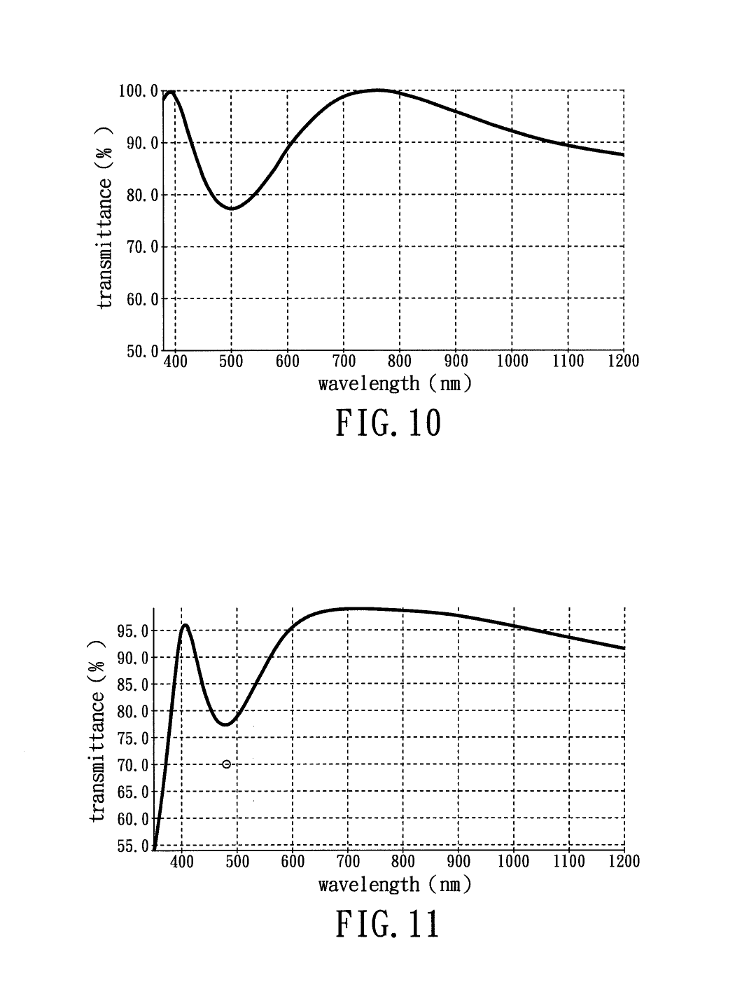

FIG. 10 is a diagram showing the transmittance of the color filter of Example 3 (E3). The color filter has a transmittance of between 90% and 100% in a wavelength band from 400 nm to 430 nm and in another wavelength band from 610 nm to 720 nm and between 77% and 90% in yet another wavelength band from 430 nm to 610 nm, and has an average transmittance of greater than 90% in a wavelength band from 400 nm to 720 nm and greater than 85% in a wavelength band from 400 nm to 1200 nm. Measured by a colorimeter, the color filter has a chromaticity coordinate of (x=0.28, y=0.37) in a CIE 1931 chromaticity coordinate diagram (not shown), which indicates a color close to green color.

FIG. 11 is a diagram showing the transmittance of the color filter of Example 4 (E4). The color filter has a transmittance of between 80% and 96% in a wavelength band from 400 nm to 460 nm, between 80% and 100% in another wavelength band from 510 nm to 720 nm and between 77% and 80% in yet another wavelength band from 460 nm to 510 nm, and has an average transmittance of greater than 90% in a wavelength band from 400 nm to 720 nm and greater than 85% in a wavelength band from 400 nm to 1200 nm. Measured by a colorimeter, the color filter has a chromaticity coordinate of (x=0.21, y=0.3) in a CIE 1931 chromaticity coordinate diagram (not shown), which indicates a color close to blue color.

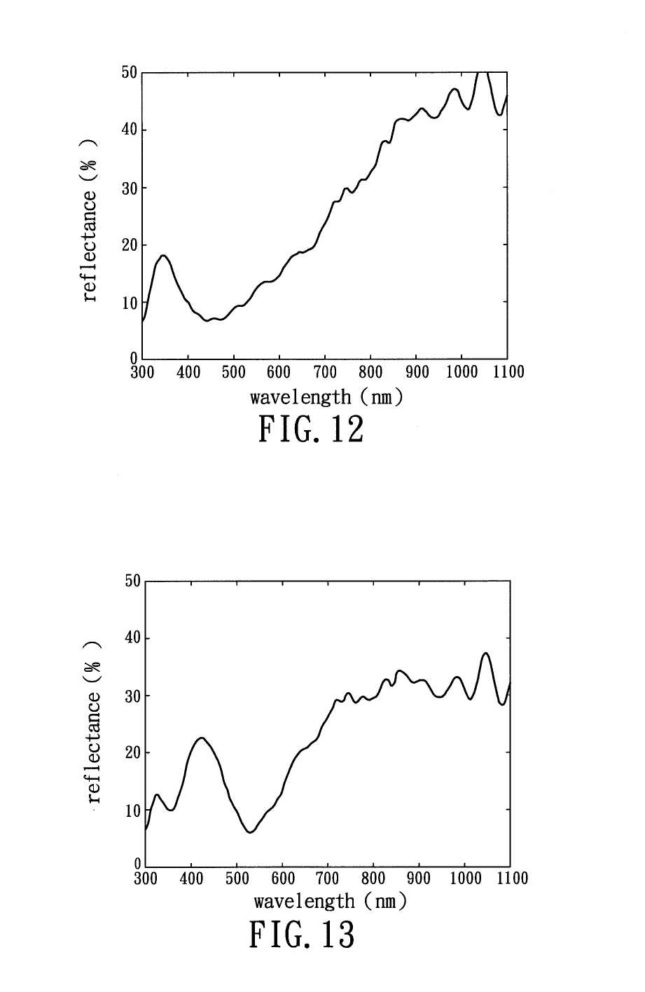

FIG. 12 is a diagram showing the reflectance of the color filter of Example 5 (E5). The color filter has a reflectance of between 10% and 25% in a wavelength band from 400 nm to 720 nm and between 25% and 50% in a wavelength band from 720 nm to 1100 nm. A transmittance measuring test shows that the color filter of Example 5 (E5) has an average transmittance of about 86% in wavelength bands from 400 nm to 540 nm and from 650 nm to 720 nm and an average transmittance of greater than 80% in a wavelength band from 400 nm to 720 nm. Measured by a colorimeter, the color filter of Example 5 (E5) has a chromaticity coordinate of (x=0.41, y=0.38) in a CIE 1931 chromaticity coordinate diagram (not shown), which indicates a color close to golden color.

FIG. 13 is a diagram showing the reflectance of the color filter of Example 6 (E6). The color filter has a reflectance of between 6% and 28% in a wavelength band from 400 nm to 720 nm and between 28% and 37% in a wavelength band from 720 nm to 1100 nm. A transmittance measuring test shows that the color filter of Example 6 (E6) has an average transmittance of about 86% in a wavelength band from 400 nm to 600 nm and an average transmittance of greater than 80% in a wavelength band from 400 nm to 720 nm. Measured by a colorimeter, the color filter of Example 6 (E6) has a chromaticity coordinate of (x=0.34, y=0.25) in a CIE 1931 chromaticity coordinate diagram (not shown), which indicates a color close to red color.

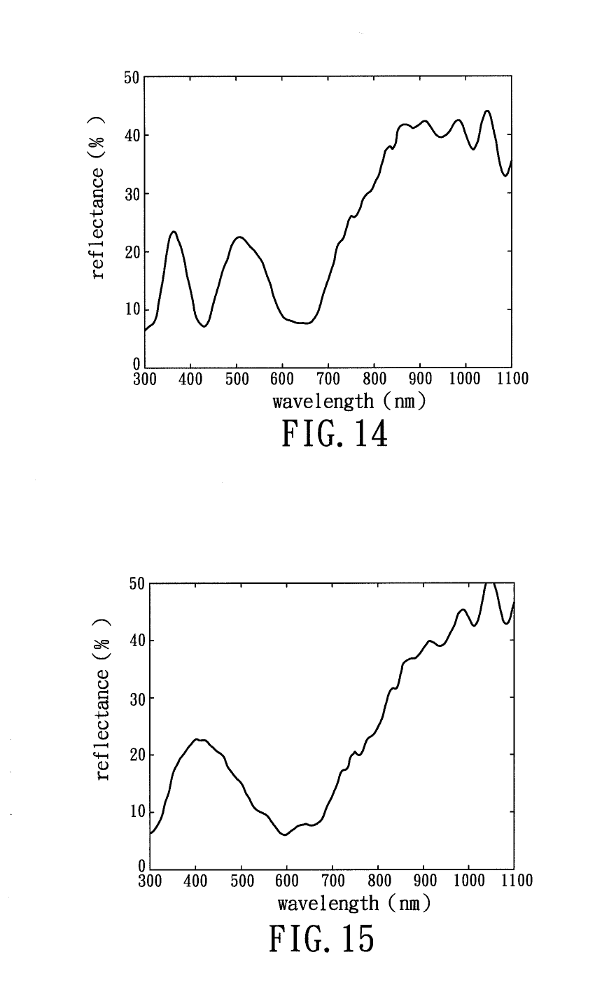

FIG. 14 is a diagram showing the reflectance of the color filter of Example 7 (E7). The color filter has a reflectance of between 8% and 23% in a wavelength band from 400 nm to 720 nm and within 20% and 44% in a wavelength band from 720 nm to 1100 nm. A transmittance measuring test shows that the color filter of Example 7 (E7) has an average transmittance of about 90% in wavelength bands from 400 nm to 450 nm and from 600 nm to 720 nm and an average transmittance of greater than 80% in a wavelength band from 400 nm to 720 nm. Measured by a colorimeter, the color filter of Example 7 (E7) has a chromaticity coordinate of (x=0.28, y=0.41) in a CIE 1931 chromaticity coordinate diagram (not shown), which indicates a color close to green color.

FIG. 15 is a diagram showing the reflectance of the color filter of Example 8 (E8). The color filter has a reflectance of between 7% and 22% in a wavelength band from 400 nm to 720 nm and between 18% and 50% in a wavelength band from 720 nm to 1100 nm. A transmittance measuring test shows that the color filter of Example 8 (E8) has an average transmittance of about 92% in a wavelength band from 550 nm to 720 nm and an average transmittance of greater than 80% in a wavelength band from 400 nm to 720 nm. Measured by a colorimeter, the color filter of Example 8 (E8) has a chromaticity coordinate of (x=0.25, y=0.26) in a CIE 1931 chromaticity coordinate diagram (not shown), which indicates a color close to blue color.

With the combination of the specific material used for forming the dielectric layer 321, 92 and the thickness thereof in the color filter 3 of the colored solar cell device of the present invention, the goal of reflecting an incident light with a desired color and transmitting the incident light with a relatively high transmittance (an average transmittance of greater than 80% in a wavelength band from 400 nm to 720 nm) can be achieved, thereby enhancing the photoelectric conversion efficiency of the solar cell module 2.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A colored solar cell device comprising:
a solar cell module having a light-incident side;
a transparent adhesive layer; and
a color filter attached to said light-incident side of said solar cell module through said transparent adhesive layer and including a transparent filter substrate and a wavelength-selective reflective film that is formed on said transparent filter substrate, that contacts said transparent adhesive layer, and that includes at least one first dielectric layer which is made from a material selected from the group consisting of TiO₂, Nb₂O₃, ZnS, and ZrO₂, said first dielectric layer having a thickness that ranges from 1 nm to 300 nm, said transparent filter substrate having a refractive index n₀, said first dielectric layer having a refractive index n₁ that is greater than n₀.

2. The colored solar cell device of claim 1, wherein the thickness of said first dielectric layer ranges from 70 nm to 90 nm, thereby permitting said color filter to reflect light of golden color.

3. The colored solar cell device of claim 1, wherein said wavelength-selective reflective film further includes a plurality of second dielectric layers, the number of said at least one first dielectric layer being greater than that of said second dielectric layers, each of said second dielectric layers being made from a material selected from the group consisting of SiO₂, LiF, and MgF₂, said first and second dielectric layers being alternately disposed, said transparent filter substrate and said transparent adhesive layer being respectively in contact with two endmost ones of said first dielectric layers, each of said second layers having a refractive index n₂ that is less than n₁, and a thickness that ranges from 1 nm to 100 nm.

4. The colored solar cell device of claim 1, wherein said wavelength-selective reflective film further includes a second dielectric layer, the number of said at least one first dielectric layer being two, said second dielectric layer being made from a material selected from the group consisting of SiO₂, LiF, and MgF₂, said second dielectric layer being disposed between said first dielectric layers; and
wherein the thickness of one of said first dielectric layers, which is disposed adjacent to said transparent filter substrate, ranges from 80 nm to 100 nm, the thickness of said second dielectric layer ranges from 5 nm to 20 nm, and the thickness of the other of said first dielectric layers, which is disposed distal from said transparent filter substrate, ranges from 95 nm to 115 nm, thereby permitting said color filter to reflect light in red color.

5. The colored solar cell device of claim 1, wherein said wavelength-selective reflecting film further includes a second dielectric layer, the number of said at least one first dielectric layer being two, said second dielectric layer being made from a material selected from the group consisting of SiO₂, LiF, and MgF₂, said second dielectric layer being disposed between said first dielectric layers; and
wherein the thickness of one of said first dielectric layers, which is disposed adjacent to said transparent filter substrate, ranges from 55 nm to 70 nm, the thickness of said second dielectric layer ranges from 4 nm to 8 nm, and the thickness of the other of said first dielectric layers, which is disposed distal from said transparent filter substrate, ranges from 70 nm to 88 nm, thereby permitting said color filter to reflect light in green color.

6. The colored solar cell device of claim 1, wherein said wavelength-selective reflecting film further includes a second dielectric layer, the number of said at least one first dielectric layer being two, said second dielectric layer being made from a material selected from the group consisting of SiO₂, LiF, and MgF₂, said second dielectric layer being disposed between said first dielectric layers; and
wherein the thickness of one of said first dielectric layers, which is disposed adjacent to said transparent filter substrate, ranges from 110 nm to 135 nm, the thickness of said second dielectric layer ranges from 40 nm to 50 nm, and the thickness of the other of said first dielectric layers, which is disposed distal from said transparent filter substrate, ranges from 6 nm to 15 nm, thereby permitting said color filter to reflect light in blue color.

7. The colored solar cell device of claim 1, wherein said transparent adhesive layer has a refractive index n_{B} that is smaller than n₁.

8. The colored solar cell device of claim 1, wherein said first dielectric layer has a bottom surface that contacts said transparent adhesive layer, and a predetermined pattern that protrudes from said bottom surface into said transparent adhesive layer.

9. A colored solar cell device comprising:
a lower substrate;
an adhesive layer;
a solar cell having a light-incident side and attached to said lower substrate through said adhesive layer; and
a color filter formed on said light-incident side of said solar cell and including a transparent filter substrate and a dielectric layer which is made from a material selected from the group consisting of TiO₂, Nb₂O₃, ZnS, and ZrO₂, and which has a thickness ranging from 1 nm to 300 nm, said transparent filter substrate having a refractive index n₀, said dielectric layer having a refractive index n₁ which is greater than n₀.

10. The colored solar cell device of claim 9, wherein the thickness of said dielectric layer of said color filter ranges from 70 nm to 90 nm, thereby permitting said color filter to reflect light in yellow color.

11. The colored solar cell device of claim 9, wherein the thickness of said dielectric layer of said color filter ranges from 180 nm to 210 nm, thereby permitting said color filter to reflect light in red color.

12. The colored solar cell device of claim 9, wherein the thickness of said dielectric layer of said color filter ranging from 210 nm to 250 nm, thereby permitting said color filter to reflect light in green color.

13. The colored solar cell device of claim 9, wherein the thickness of said dielectric layer of said color filter ranging from 100 nm to 120 nm, thereby permitting said color filter to reflect light in blue color.

14. The colored solar cell device of claim 9, wherein said first dielectric layer has a bottom surface that contacts said solar cell, and a predetermined pattern that protrudes from said bottom surface into said solar cell.
